(19) United States
(12) Patent Application Publication
(10) Pub. No.: US 2026/0122784 A1
(43) Pub. Date: Apr. 30, 2026

(54) PACKAGE STRUCTURE

(71) Applicant: Advanced Semiconductor Engineering, Inc., Kaohsiung (TW)

(72) Inventors: Chao Wei LIU, Kaohsiung (TW); Wei-Hao CHANG, Kaohsiung (TW); Yu-Chang CHEN, Kaohsiung (TW)

(73) Assignee: Advanced Semiconductor Engineering, Inc., Kaohsiung (TW)

(21) Appl. No.: 18/927,800

(22) Filed: Oct. 25, 2024

(51) Int. Cl. H05K 1/14; H01L 23/00; H01L 23/538; H01L 25/16; H05K 1/02; H05K 1/11; H05K 1/18; H05K 3/28; H05K 3/30

(52) U.S. Cl. CPC H05K 1/144; H05K 1/0271; H05K 1/111; H05K 1/181; H05K 3/284; H05K 3/303; H10W 42/121; H10W 70/611; H10W 90/00; H10W 90/401; H05K 2201/042; H05K 2201/10015

(57) ABSTRACT

A package structure is provided. The package structure includes a first substrate, a second substrate, a connection element, and a compression element. The second substrate is disposed over the first substrate. The connection element includes a first contact extending between the first substrate and the second substrate to connect the first substrate to the second substrate. The compression element is disposed over the first substrate and including a portion extending from a top surface toward a bottom surface of the first substrate and is configured to reduce warping of the first substrate in a first direction away from the second substrate.

### BACKGROUND

### 1. Technical Field

The present disclosure relates generally to a package structure.

### 2. Description of the Related Art

Typically, in a package structure where an upper substrate is directly bonded to a lower substrate through passive elements, the solder materials for connecting the passive elements to the substrates may be relatively thin. As a result, delamination may easily occur when the upper substrate is warped.

### SUMMARY

In one or more arrangements, a package structure includes a first substrate, a second substrate, a connection element, and a compression element. The second substrate is disposed over the first substrate. The connection element includes a first contact extending between the first substrate and the second substrate to connect the first substrate to the second substrate. The compression element is disposed over the first substrate and including a portion extending from a top surface toward a bottom surface of the first substrate and is configured to reduce warping of the first substrate in a first direction away from the second substrate.

In one or more arrangements, a package structure includes a first substrate, a second substrate, a first passive component, a second passive component, and a clamping mechanism. The second substrate is disposed over the first substrate. The first passive component and the second passive component connect the first substrate to the second substrate. The first passive component is closer to an edge of the first substrate than the second passive component is. The clamping mechanism encapsulates the first substrate, the first passive component and the second passive component and adhered to the second substrate, wherein the clamping mechanism includes a first portion under the first passive component.

In one or more arrangements, a package structure includes a first substrate, a second substrate, a plurality of passive components, and a warpage control element. The first substrate has a first surface and a second surface opposite to the first surface. The second substrate is disposed over the first substrate. The passive components are arranged in a single layer and connect the first substrate to the second substrate. The warpage control element is between the first surface of the first substrate and the second substrate and extends over the second surface of the first substrate.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of a portion of a package structure in accordance with some arrangements of the present disclosure.

FIG. 1C is a cross-section of a portion of a package structure in accordance with some arrangements of the present disclosure.

FIG. 1D is a cross-section of a package structure in accordance with some arrangements of the present disclosure.

FIG. 2A is a cross-section of a package structure in accordance with some arrangements of the present disclosure.

FIG. 2B is a cross-section of a package structure in accordance with some arrangements of the present disclosure.

FIG. 3A to FIG. 3J illustrate various stages of an exemplary method of forming a package structure in accordance with some arrangements of the present disclosure.

FIG. 4A to FIG. 4E illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

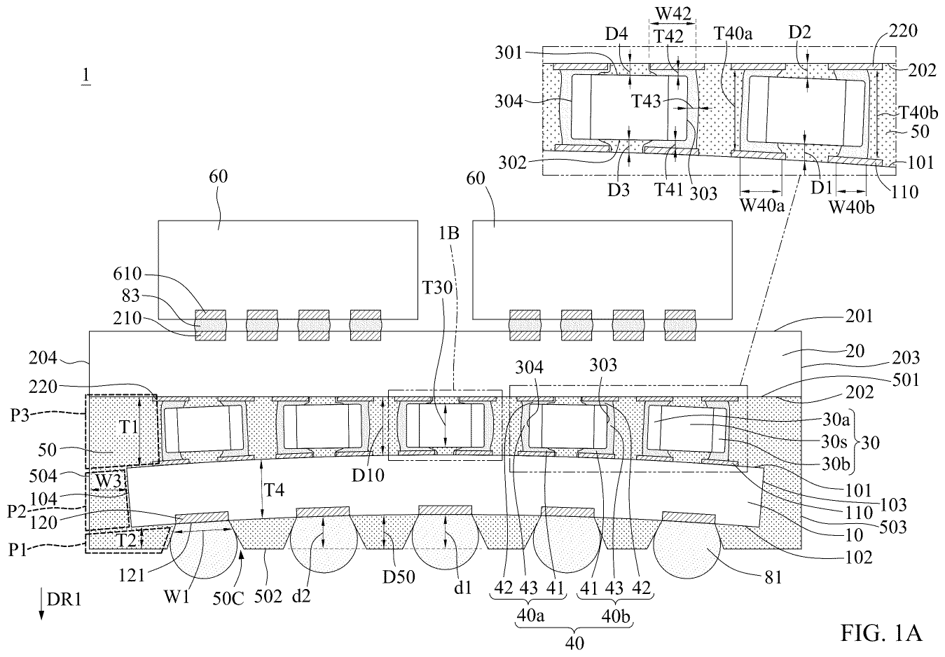

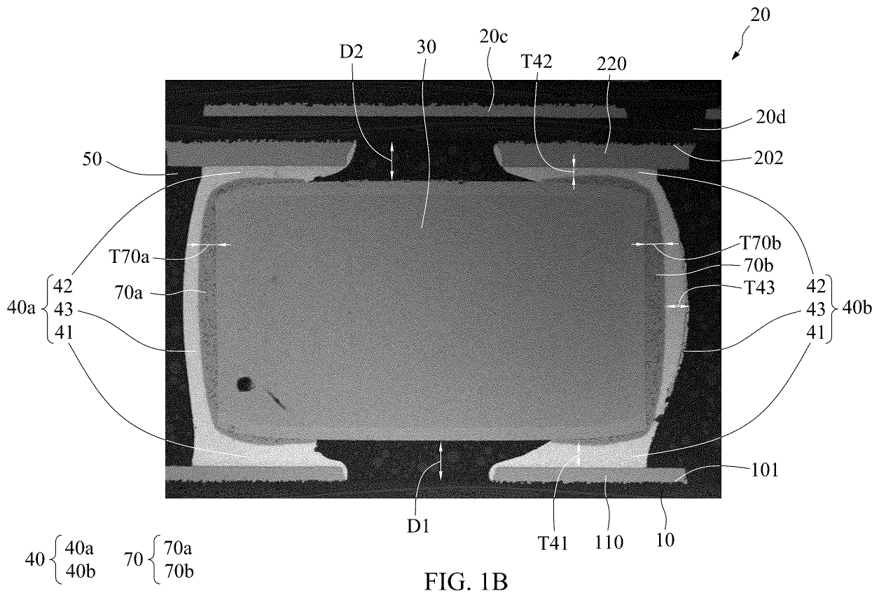

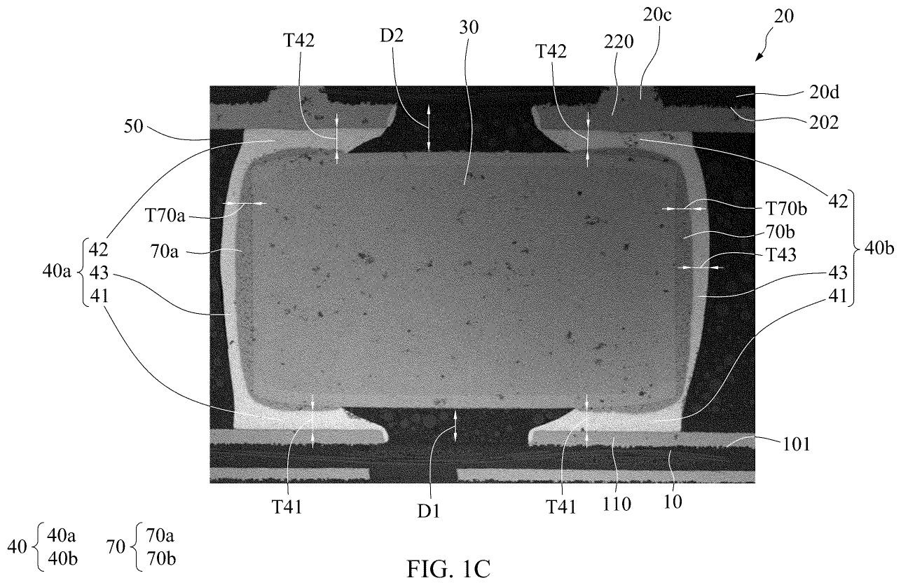

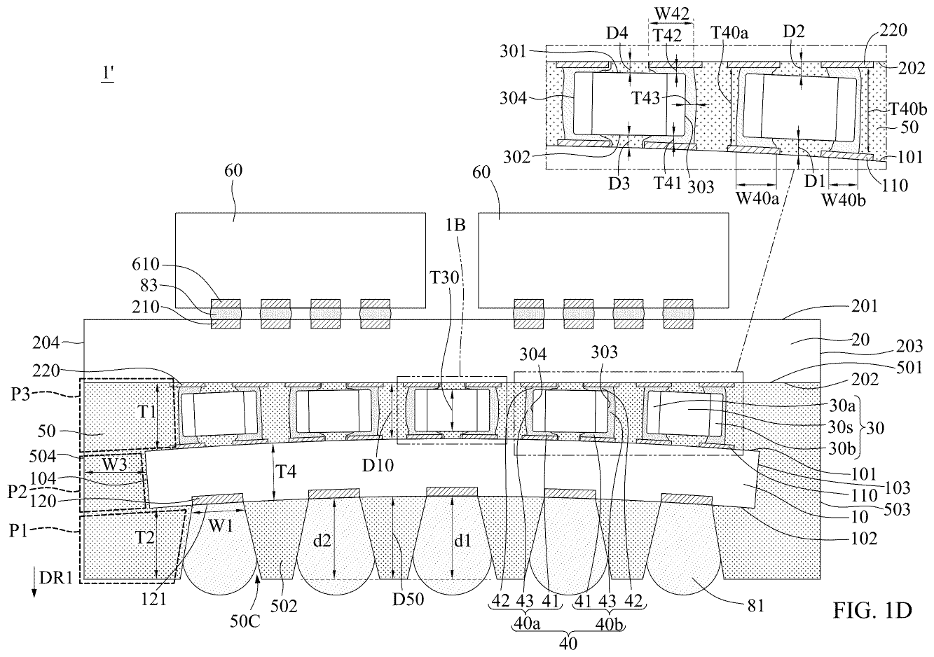

FIG. 1A is a cross-section of a package structure 1 in accordance with some arrangements of the present disclosure. The package structure 1 may include substrates 10 and 20, passive components 30, reflowable elements 40, a protective element 50, electronic components 60, and electrical contacts 81. The package structure 1 may be or include a system-in-package (SiP).

Embodiments of the present disclosure discuss a package structure including a structure configured to reduce a warpage of a substrate. The package structure includes a plurality of connection elements (e.g., the passive components 30) and a plurality of solder elements (e.g., the reflowable elements 40) which connect the substrate 10 to the substrate 20, and each of the connection elements includes contacts (e.g., electrodes 30a and 30b) that extend between the substrate 10 and the substrate 20 and contacting the solder elements. The contacts extend along sidewalls of the connection element and thus have a relatively large contact area, and the solder element connects to the contact area without being defined by a solder mask or being accommodated in an opening of a solder mask. As a result, the solder element extends over the relatively large contact area, and thus the solder element may expand in area and have a relatively small thickness along the sidewalls of the connection element as well as between the connection element and the substrates 10 and 20. Therefore, when the substrate 10 is warped, the relatively thin portion of the solder element may be detached from the substrate 10 or crack. To solve the above delamination and cracking issue, the structure (e.g., the protective element 50) that is configured to press the substrate 10 and reduce the warpage of the substrate 10, thus the delamination due to the relatively thin solder element can be prevented.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may include a surface 101 (also referred to as a top surface or an upper surface), a surface 102 (also referred to as a bottom surface or a lower surface) opposite to the surface 101, and lateral surfaces 103 and 104 extending between the surface 101 and the surface 102. In some arrangements, the surface 101 of the substrate 10 faces the substrate 20. The surfaces 101 and 102 may be or include curved surfaces. The lateral surface 103 may be non-parallel to the lateral surface 104. In some arrangements, the substrate 10 includes conductive pads 110 exposed from the surface 101. In some arrangements, the substrate 10 includes conductive pads 120 exposed from the surface 102.

The substrate 20 may be disposed over the substrate 20. The substrate 20 may include, for example, a printed circuit board, such as a paper-based copper foil laminate, a composite copper foil laminate, or a polymer-impregnated glass-fiber-based copper foil laminate. The substrate 20 may include an interconnection structure, such as a plurality of conductive traces and/or a plurality of conductive vias. In some arrangements, the substrate 20 includes a ceramic material, a metal plate, an organic substrate, or a leadframe. In some arrangements, the substrate 20 may include a two-layer substrate which includes a core layer and a conductive material and/or structure disposed on an upper surface and a bottom surface of the substrate 20. The conductive material and/or structure may include a plurality of conductive traces. The substrate 20 may include a surface 201 (also referred to as a top surface or an upper surface), a surface 202 (also referred to as a bottom surface or a lower surface) opposite to the surface 201, and lateral surfaces 203 and 204 extending between the surface 201 and the surface 202. The lateral surface 203 may be substantially parallel to the lateral surface 204. In some arrangements, the substrate 20 includes conductive pads 210 exposed from the surface 201. In some arrangements, the substrate 20 includes conductive pads 120 exposed from the surface 202. In some arrangements, the substrate 10 and the substrate 20 are spaced apart from each other by a non-uniform distance D10. The distance D10 may increase from a center region toward a peripheral region of the package structure 1. In some arrangements, a warpage of the substrate 10 is greater than a warpage of the substrate 20.

The passive components 30 may connect the substrate 10 to the substrate 20. The passive components 30 may be referred to as connection elements. In some arrangements, the passive components 30 include surface mount devices (SMDs). In some arrangements, the passive components 30 include capacitors or the like. In some arrangements, the passive component 30 includes a base layer 30s and electrodes 30a and 30b (also referred to as “contacts”). The electrode 30a may be opposite to the electrode 30b. The electrodes 30a and 30b extend between the substrate 10 and the substrate 20 to connect the substrate 10 to the substrate 20. The base layer 30s may be an insulating layer, e.g., a ceramic layer. In some arrangements, the passive components 30 are arranged in a single layer between the substrate 10 and the substrate 20. In some arrangements, the passive components 30 are arranged in a single layer to connect the substrate 10 to the substrate 20. In some arrangements, the distance D10 between the substrate 10 and the substrate 20 is defined by a thickness T30 of the passive component 30.

In some arrangements, at least two of the passive components 30 are spaced apart from the substrate 10 by different distances. In some arrangements, one of the passive components 30 is spaced apart from the substrate 10 by a distance D1, and another one of the passive components 30 is spaced apart from the substrate 10 by a distance D3 different from the distance D1. In some arrangements, the distance D3 is greater than the distance D1. In some arrangements, one of the passive components 30 is spaced apart from the substrate 10 by the distance D1 and spaced apart from the substrate 20 by a distance D2 different from the distance D1. In some arrangements, the distance D1 is greater than the distance D2. In some arrangements, one of the passive components 30 is spaced apart from the substrate 10 by the distance D3 and spaced apart from the substrate 20 by a distance D4 different from the distance D3. In some arrangements, the distance D3 is greater than the distance D4.

The passive components 30 may include a surface 301 (also referred to as a top surface or an upper surface), a surface 302 (also referred to as a bottom surface or a lower surface) opposite to the surface 301, and lateral surfaces 303 and 304 extending between the surface 301 and the surface 302. In some arrangements, the surfaces 301 and 302 are non-parallel to the surface 202 of the substrate 20. In some arrangements, the lateral surfaces 303 and 304 are non-parallel to the lateral surfaces 203 and 204 of the substrate 20.

The reflowable elements 40 may be disposed between the substrate 10 and the substrate 20. In some arrangements, the reflowable element 40 connects the passive component 30 to the conductive pad 110 of the substrate 10 and the conductive pad 210 of the substrate 20. In some arrangements, the reflowable element 40 contacts the passive component 30, the conductive pad 110 of the substrate 10, and the conductive pad 210 of the substrate 20. In some arrangements, the reflowable element 40 contacts the electrodes 30a and 30b of the passive component 30. In some arrangements, the distance D10 between the substrate 10 and the substrate 20 is defined by a height (e.g., heights T40a and T40b) of the reflowable elements 40. The reflowable elements 40 may be or include solder elements.

In some arrangements, the reflowable element 40 includes a portion 40a and a portion 40b spaced apart from the portion 40a in a cross-sectional view perspective. In some arrangements, the portion 40a contacts the lateral side (or the lateral surface 303) of the passive component 30, and the portion 40b contacts the lateral side (or the lateral surface 304) of the passive component 30. In some arrangements, a height T40a of the portion 40a is different from a height T40b of the portion 40b. In some arrangements, the height T40a of the portion 40a is greater than the height T40b of the portion 40b. In some arrangements, a width W40a of the portion 40a is different from a width W40b of the portion 40b. In some arrangements, the width W40a of the portion 40a is less than the width W40b of the portion 40b.

In some arrangements, the reflowable element 40 includes portions 41, 42, and 43. In some arrangements, each of the portions 40a and 40b of the reflowable element 40 includes portions 41, 42, and 43. In some arrangements, the portion 41 extends over a portion of the surface 301 of the passive component 30, the portion 43 extends over a portion of the surface 302 of the passive component 30, and the portion 42 extends over a portion of the lateral surface (e.g., the lateral surface 303 and 304) of the passive component 30.

In some arrangements, the portion 41 connects the passive component 30 to the substrate 10, and the portion 42 connects the passive component 30 to the substrate 20. In some arrangements, a thickness T41 of the portion 41 is greater than a thickness T42 of the portion 42. In some arrangements, the portion 43 contacts the portion 41 and the portion 42. In some arrangements, the portion 41 connects the passive component 30 to the conductive pad 110 of the substrate 10, the portion 42 connects the electrode 30a of the passive component 30 to the conductive pad 220 of the substrate 20, and the portion 43 contacts the lateral surface 303 (and/or the lateral surface 304) of the passive component 30. In some arrangements, a width W42 of the portion 42 is greater than the thickness T42 of the portion 42. In some arrangements, for the reflowable element 40 adjacent to the passive component 30 that is adjacent to a center region of the package structure 1, the thickness T42 of the portion 42 is less than a thickness T43 of the portion 43, and the thickness T43 of the portion 43 is greater than the thickness T41 of the portion 41. In some arrangements, for the reflowable element 40 adjacent to the passive component 30 that is adjacent to a peripheral region of the package structure 1, the thickness T42 of the portion 42 is greater than the thickness T43 of the portion 43, and the thickness T43 of the portion 43 is less than the thickness T41 of the portion 41.

The protective element 50 may be disposed over the substrate 10. In some arrangements, the protective element 50 connects the surface 101 (or the top surface) of the substrate 10 to the surface 202 (or the bottom surface) of the substrate 20. In some arrangements, the protective element 50 extends from the surface 102 toward the surface 101 of the substrate 10 to connect to the substrate 20. In some arrangements, the protective element 50 contacts the surface 101 of the substrate 10 and the surface 202 of the substrate 20. In some arrangements, the protective element 50 extends over at least a portion of the surface 102 of the substrate 10. In some arrangements, the protective element 50 contacts the surface 102 of the substrate 10.

The protective element 50 may have a surface 501 (also referred to as a top surface or an upper surface), a surface 502 (also referred to as a bottom surface or a lower surface) opposite to the surface 501, and lateral surfaces 503 and 504 extending between the surface 501 and the surface 502. In some arrangements, the surface 502 (or the bottom surface) of the protective element 50 is spaced apart from the surface 102 of the substrate 10 by a non-uniform distance D50. The distance D50 may decrease from a center region toward a peripheral region of the package structure 1.

The protective element 50 may be referred to as a compression element, a reinforcement element, or a warpage control element. In some arrangements, the protective element 50 (or the compression element) is configured to reduce warping of the substrate 10 in a direction DR1 away from the substrate 20. In some arrangements, the protective element 50 (or the compression element) is configured to press the substrate 10 by applying a force towards the substrate 20. In some arrangements, the protective element 50 (or the reinforcement element) is configured to reduce a warpage of the substrate 10.

In some arrangements, portions of the surface 102 of the substrate 10 are exposed by the protective element 50. In some arrangements, the protective element 50 defines a plurality of cavities 50C configured to accommodate the electrical contacts 81. In some arrangements, at least two of the cavities 50C are recessed from the surface 502 by different depths (e.g., depths d1 and d2). In some arrangements, the protective element 50 includes an encapsulant. The encapsulant may include an epoxy resin having fillers dispersed therein, a molding compound (e.g., an epoxy molding compound or other molding compound), polyimide (PI), a phenolic compound or material, a polymer material with silicone dispersed therein, or a combination thereof.

In some arrangements, the protective element 50 extends from the surface 101 toward the surface 102 of the substrate. In some arrangements, the protective element 50 includes portions P1, P2, and P3. The portion P3 may have thickness T1, the portion P2 may have a width W3, and the portion P1 may have a thickness T2. In some arrangements, the portion P3 is adhered to the substrate 20, the portion P2 is at a lateral side of the substrate 10, and the portion P1 is under the passive component 30. The portion P1 is configured to limit the substrate 10 from warping away from the substrate 20. The warpage of the substrate 10 is relatively large at an edge portion of the substrate 10 compare to that at a center portion of the substrate 10. With the portion P1 under the surface 102 of the substrate 10 and at an edge portion of the substrate 10, delamination between the reflowable element 40 and the conductive pads 110 of the substrate 10 resulted from the warpage of the substrate 10 can be prevented. Therefore, failure of electrical connection between the substrates 10 and 20 through the passive components 30 and the reflowable elements 40 can be prevented.

In some arrangements, the portions P1, P2, and P3 collectively construct a clamping mechanism to grip the edge portion of the substrate 10. In some arrangements, the portions P1 and P2 are configured to fasten or fix the position of the substrate 10, and the portion P3 connects the portions P1 and P2 to the surface 202 of the substrate 20 to further fix the relative position of the portions P1 and P2. Therefore, the position shift of the edge portion of the substrate 10 can be further prevented, and thus the warpage can be reduced effectively.

The electronic components 60 may be disposed over and electrically connected to the substrate 20. In some arrangements, the electronic component 60 includes conductive pads 610 exposed by a surface (e.g., an active surface) of the electronic component 60. In some arrangements, the conductive pads 610 are connected to the conductive pads 210 through connection elements 83. The connection element 83 may be or include conductive bumps. The electronic component 60 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the electronic component 60 may be or include a processing component, e.g., an ASIC, an FPGA, a GPU, or the like, or a combination thereof.

The electrical contacts 81 may be disposed over the surface 102 of the substrate 10. In some arrangements, the electrical contacts 81 are disposed on and electrically connected to the conductive pads 120 of the substrate 10. In some arrangements, lower surfaces 121 of the conductive pads 120 contact the electrical contacts 81 and are non-parallel to the surface 502 of the protective element 50. The electrical contacts 81 may be or include solder elements (e.g., solder bumps, solder balls, or the like). In some embodiments, the electrical contacts 81 include controlled collapse chip connection (C4) bumps, a ball grid array (BGA), or a land grid array (LGA). In some arrangements, the electrical contact 81 (or the solder element) has a width W1 increasing along the direction DR1. In some arrangements, the electrical contact 81 (or the solder element) contacts the protective element 50. In some arrangements, the electrical contact 81 (or the solder element) is engaged with a portion of the protective element 50 and configured to provide a mold lock to increase a bonding strength between the protective element 50 and the substrate 10. In some arrangements, the electrical contacts 81 contact portions of the surface 102 of the substrate 10 that are exposed by the protective element 50.

In some cases where the surface 102 of the substrate 10 may be exposed by the protective element 50, such that the electrical contacts 81 can be formed on the exposed surface 102 for bonding to external components. However, the substrate 10 may warp toward a direction away from the substrate 20 by a thermal operation during the manufacturing process, such that delamination may occur between the substrate 10 and the protective element 50 or between the passive components 30 and the protective element 50.

According to some arrangements of the present disclosure, the protective element 50 further extends over a portion of the surface 102 of the substrate 10, and thus the protective element 50 can serve as a reinforcement element that is configured to reduce the warpage of the substrate 10.

In additional, according to some arrangements of the present disclosure, the protective element 50 connects to the surface 101 of the substrate 10 and further extends along the lateral surfaces 103 and 104 to connect to a portion of the surface 102 of the substrate 10. Thus, the protective element 50 may serve as a compression element that is configured to press the substrate 10 by applying a force towards the substrate 20 and reducing warping of the substrate 10 in the direction DR1 away from the substrate 20. Therefore, delamination can be prevented, and thus the reliability of the package structure 1 is improved.

Moreover, according to some arrangements of the present disclosure, the protective element 50 covers the lateral surfaces 103 and 104 of the substrate 10. Therefore, the edge portions of the substrate 10 can be prevented from being damaged by impact.

Furthermore, according to some arrangements of the present disclosure, the protective element 50 encapsulates a single layer of passive components 30 and the reflowable elements 40 with portions 41 and 42 having relatively small thicknesses (e.g., the thicknesses T41 and T42). The substrates 10 and 20 are separated from each other and connected to each other by the single layer of passive components 30, and the portions 41 and 42 that connect the passive components 30 to the substrates 10 and 20 are relatively thin, thus the height of the package structure 1 can be reduced, and the power path passing the substrate 10 and the substrate 20 toward the electronic components 60 can be relatively short. Therefore, the power efficiency can be improved. In addition to the above, the protective element 50 further press the substrate 10 toward the substrate 20 to reduce the warpage of the substrate 10, and thus the delamination between the reflowable element 40 and the substrates 10 and 20 and the delamination between the reflowable element 40 and the passive component 30 can be prevented despite that the portions 41 and 42 are relatively thin. Accordingly, the reliability of the package structure 1 is improved significantly.

FIG. 1B is a cross-section of a portion of a package structure 1 in accordance with some arrangements of the present disclosure. In some arrangements, FIG. 1B shows a portion 1B of the package structure 1 illustrated in FIG. 1A.

In some arrangements, the package structure 1 further includes an interlayer 70 between the reflowable element 40 and the passive component 30. In some arrangements, the interlayer 70 includes a portion 70a between the passive component 30 and the portion 40a of the reflowable element 40 and a portion 70b between the passive component 30 and the portion 40b of the reflowable element 40. In some arrangements, a thickness T70a of the portion 70a is different from a thickness T70b of the portion 70b. In some arrangements, the thickness T70a and the thickness T70b are non-uniform. In some arrangements, the interlayer 70 is or includes a conductive layer. In some arrangements, the interlayer 70 is or includes an intermetallic compound (IMC) layer formed by a metal material of the reflowable element 40 and metal material of an electrode of the passive component 30.

In some arrangements, the thickness T41 of the portion 41 of the reflowable element 40 is non-uniform. In some arrangements, the thickness T42 of the portion 42 of the reflowable element 40 is non-uniform. In some arrangements, the thickness T43 of the portion 43 of the reflowable element 40 is non-uniform. In some arrangements, the portion 41 has a tapered cross-sectional profile. In some arrangements, the portion 43 has a convex curved surface.

In some arrangements, the substrate 20 further includes a dielectric layer 20d and a conductive layer 20c in the dielectric layer 20d. In some arrangements, the conductive layer 20c is electrically connected to the conductive pad 220.

FIG. 1C is a cross-section of a portion of a package structure 1 in accordance with some arrangements of the present disclosure. In some arrangements, FIG. 1C shows a portion 1B of the package structure 1 illustrated in FIG. 1A. The structure shown in FIG. 1C is similar to that in FIG. 1B, and the differences therebetween are described as follows.

In some arrangements, the thickness T42 of the portion 42 of the reflowable element 40 is greater than the thickness T41 of the portion 41 of the reflowable element 40.

FIG. 1D is a cross-section of a package structure 1′ in accordance with some arrangements of the present disclosure. The package structure 1′ is similar to the package structure 1 in FIG. 1A, and the differences therebetween are described as follows.

In some arrangements, the width W3 of the portion P2 is equal to or greater than the thickness T1 of the portion P3. In some arrangements, the width W3 of the portion P2 is equal to or greater than s thickness T4 of the substrate 10. In some arrangements, the thickness T2 of the portion P is equal to or greater than the thickness T1 of the portion P3.

According to some arrangements of the present disclosure, the portion P1 having a relatively large thickness T2 (e.g., thicker than the portion P3) can provide a greater compression force to limit the substrate 10 from warping away from the substrate 20. In addition, the portion P2 having a relatively large width W3 (e.g., greater than the thickness T1 and the thickness T4), can provide a greater compression force to limit edge portion of the substrate 10 from warping away from the substrate 20. Moreover, with the relatively large width W3 of the portion P2, the sizes of the portions P1 and P3 are increased as well, such that the clamping mechanism formed of the portions P1, P2, and P3 can provide a greater grip to the edge portion of the substrate 10. Therefore, the position shift of the edge portion of the substrate 10 can be further prevented, and thus the warpage can be reduced effectively.

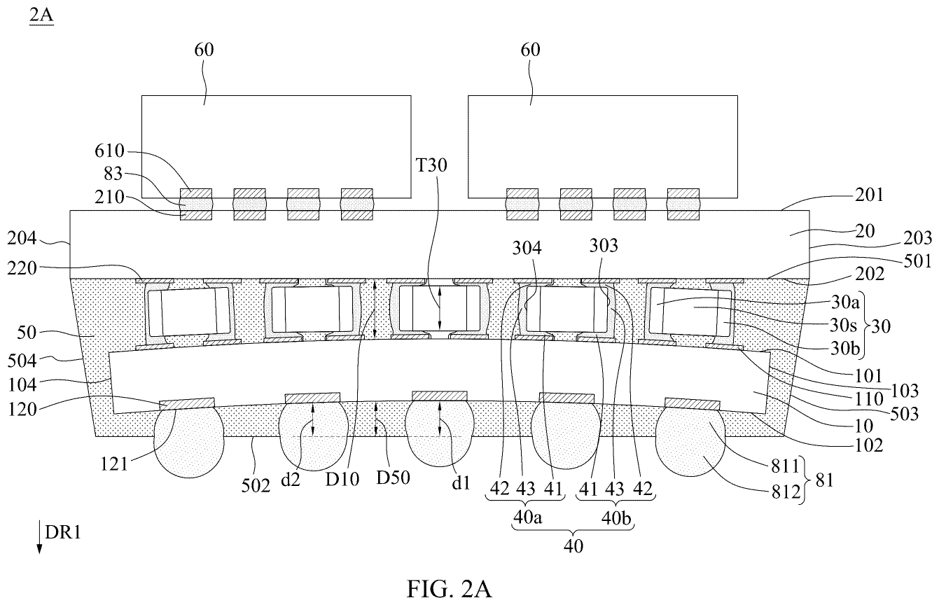

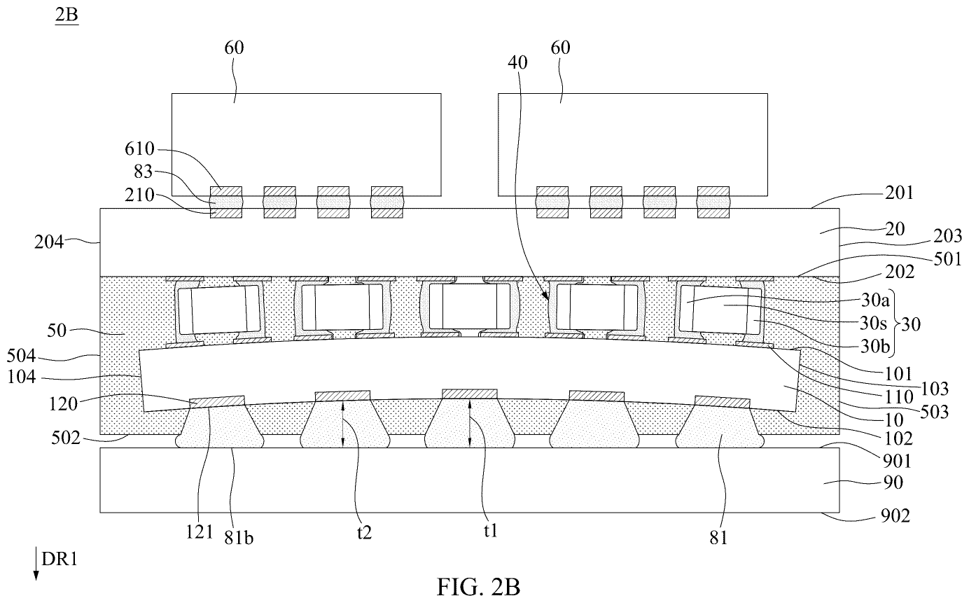

FIG. 2A is a cross-section of a package structure 2A in accordance with some arrangements of the present disclosure. The package structure 2A is similar to the package structure 1 in FIG. 1A, and the differences therebetween are described as follows.

In some arrangements, the protective element 50 has a tapered cross-sectional profile. In some arrangements, the lateral surfaces 503 and 504 are non-parallel to each other. In some arrangements, the electrical contacts 81 contact the protective element 50, and there is substantially free of a gap or a seam between the electrical contacts 81 and the protective element 50. In some arrangements, the electrical contact 81 includes a portion 811 embedded in the protective element 50 and a portion 812 protruded beyond the surface 502 of the protective element 50. In some arrangements, the portions 811 and 812 define curved surfaces connected to each other.

FIG. 2B is a cross-section of a package structure 2B in accordance with some arrangements of the present disclosure. The package structure 2B is similar to the package structure 1 in FIG. 1A, and the differences therebetween are described as follows.

In some arrangements, the package structure 2B further includes an electronic component 90 electrically connected to the substrate 10 through the electrical contacts 81. The electronic component 90 may have a surface 901 (or an active surface) and a surface 902 opposite to the surface 901. In some arrangements, at least two of the electrical contacts 81 have different thicknesses (e.g., thicknesses t1 and t2). In some arrangements, bottom surfaces 81b of the electrical contacts 81 contact the surface 901 of the electronic component 90.

The electronic component 90 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the electronic component 90 may be or include a processing component, e.g., an ASIC, an FPGA, a GPU, or the like, or a combination thereof. In some arrangements, the electronic component 90 may be or include a power module configured to provide power to the electronic components 60 with the passive components 30 serving as decoupling capacitors for the power.

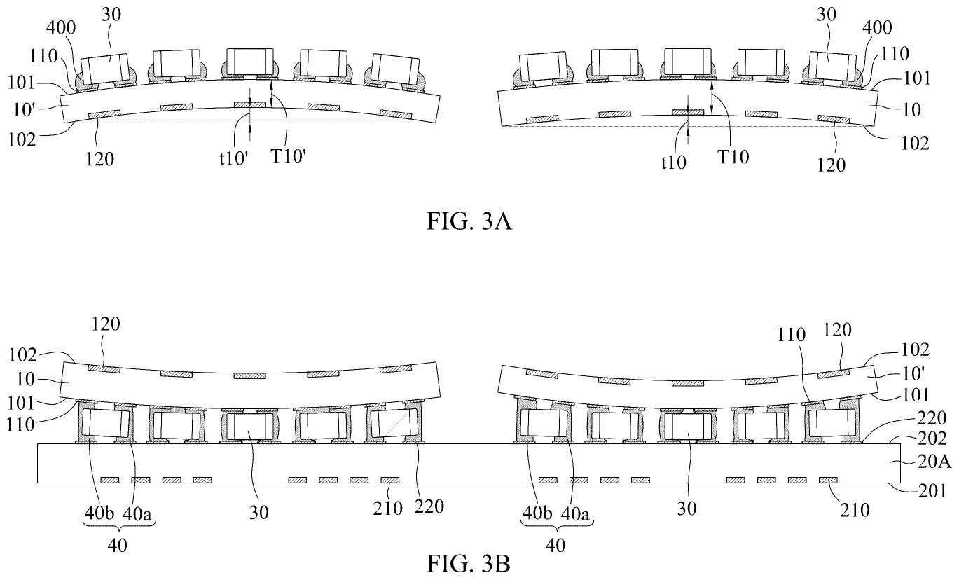

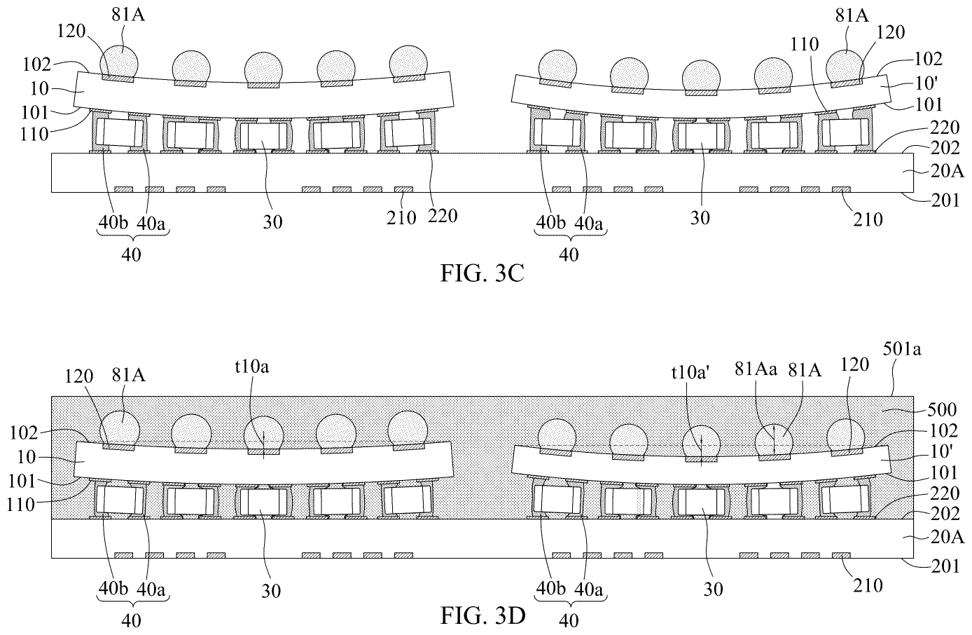

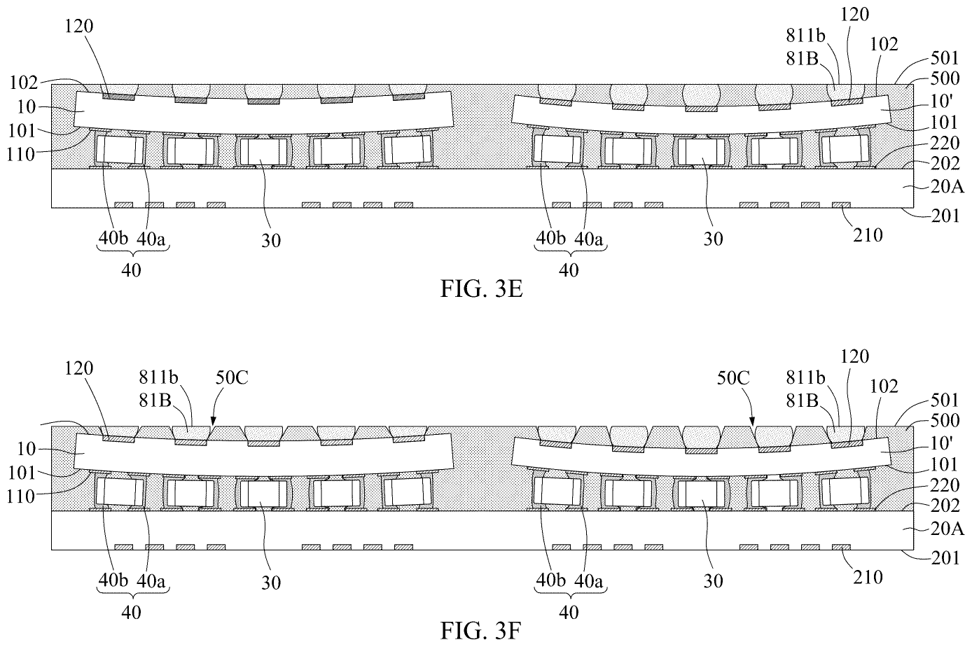

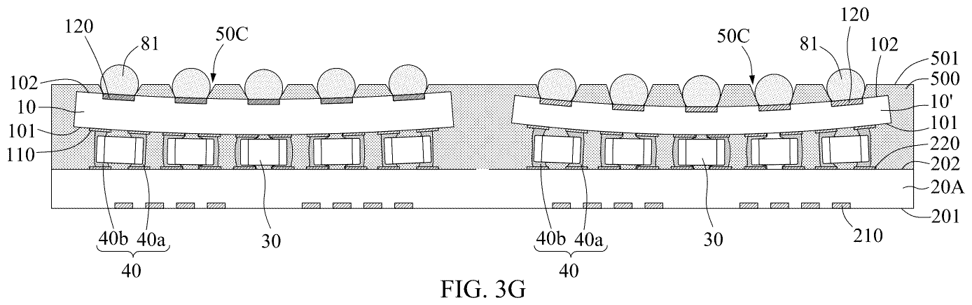

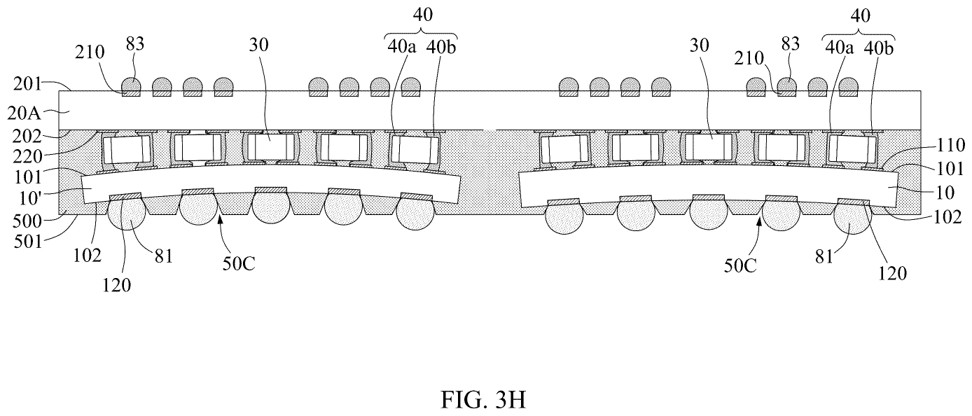

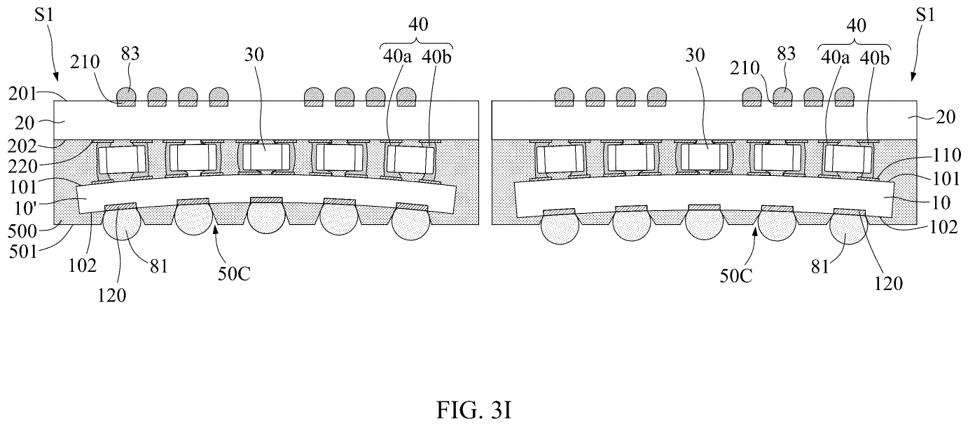

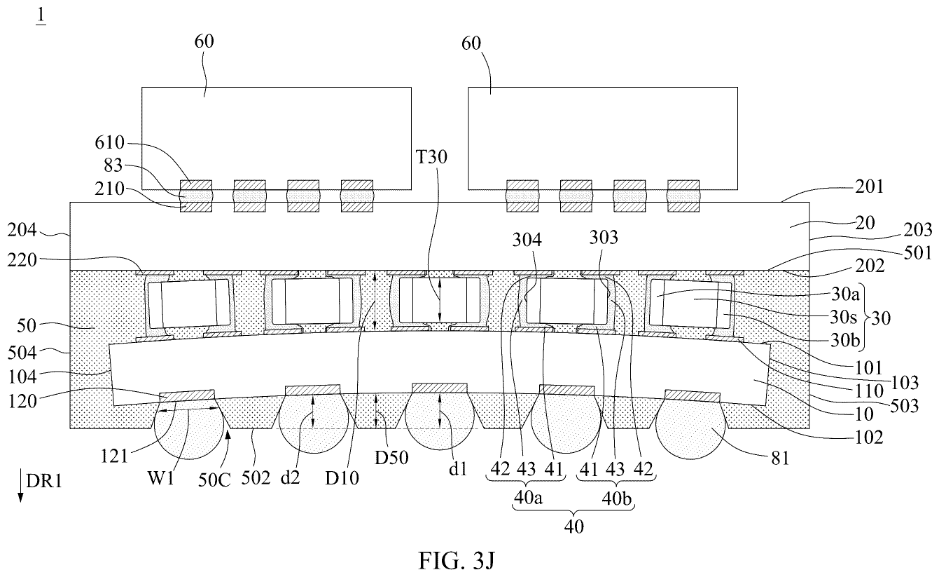

FIG. 3A to FIG. 3J illustrate various stages of an exemplary method of forming a package structure in accordance with some arrangements of the present disclosure.

Referring to FIG. 3A, a plurality of substrates 10 and 10′ may be provided. In some arrangements, a wafer-level substrate is provided, passive components 30 are connected to the wafer-level substrate through reflowable elements 400, and then the wafer-level substrate is singulated into a plurality of substrates 10 and 10′. The reflowable elements 400 may be or include solder elements. In some arrangements, warpages of the substrates 10 and 10′ may be different from each other. In some arrangements, a thickness T10 of the substrate 10 is greater than a thickness T10′ of the substrate 10′, and a warpage t10 of the substrate 10 is less than a warpage t10′ of the substrate 10′. In some arrangements, the wafer-level substrate may have a non-uniform thickness, thus the singulated substrates 10 and 10′ may have different thicknesses T10 and T10′.

Referring to FIG. 3B, the substrates 10 and 10′ may be connected to a wafer-level substrate 20A. In some arrangements, the passive components 30 on the substrates 10 and 10′ are connected to the wafer-level substrate 20A through reflowable elements, and the a reflow operation may be performed to form reflowable elements 40 from the reflowable elements 400 and the reflowable elements applied in the current stage. The reflowable elements 40 may be or include solder elements.

Referring to FIG. 3C, electrical contacts 81A may be disposed on the conductive pads 120 of the substrate 10. The electrical contacts 81A may include solder elements.

Referring to FIG. 3D, a protective element 500 may be disposed over and covering the substrates 10 and 10′. In some arrangements, the protective element 500 covers the electrical contacts 81. In some arrangements, a top surface 501a of the protective element 500 is higher than surfaces 102 of the substrates 10 and 10′ by a predetermined height. In some arrangements, the predetermined height is greater than the warpage t10 of the substrate 10 and the warpage t10′ of the substrate 10′, such that the top surface 501a of the protective element 500 is high enough to cover the surfaces 102 of the substrates 10 and 10′. In some arrangements, the protective element 500 includes fillers, and the predetermined height is greater than a height 81Aa of the electrical contact 81A plus two times a size of the fillers in the protective element 500, such that the top surface 501a of the protective element 500 is high enough to cover the surfaces 102 of the substrates 10 and 10′.

Referring to FIG. 3E, portions of the protective element 500 and portions of the electrical contacts 81A may be removed to expose electrical contacts 81B having substantially planar top surfaces 811b that are substantially aligned with a top surface (e.g., the surface 501) of the protective element 500. The protective element 500 and the electrical contacts 81A may be partially removed by a grinding operation.

Referring to FIG. 3F, portions of the protective element 500 may be further removed to form cavities 50C that expose portions of lateral surfaces of the electrical contacts 81B. The protective element 500 may be further partially removed by a laser ablation operation.

Referring to FIG. 3G, additional solder materials may be disposed on the electrical contacts 81B, and a reflow operation may be performed to melt the electrical contacts 81B and the additional solder materials to form electrical contacts 81. In some arrangements, the additional solder materials may be disposed or dispensed on the electrical contacts 81B and in the cavities 50C. The electrical contacts 81B may have insufficient height for bonding, and the additional solder materials allow the as-formed electrical contacts 81 have sufficient stand-off height for bonding.

Referring to FIG. 3H, the structure illustrated in FIG. 3G may be flipped over, and connection elements 83 may be disposed or formed on conductive pads 210 of the wafer-level substrate 20A.

Referring to FIG. 3I, a singulation operation may be performed on the structure illustrated in FIG. 3H to form a plurality of singulated structures S1.

Referring to FIG. 3J, electronic components 60 may be disposed over and connected to the singulated structure S1 to form the package structure 1 illustrated in FIG. 1A.

In some arrangements, referring to FIG. 2B, an electronic component 90 may be connected to the electrical contacts 81 followed by a reflow operation to form the package structure 2B illustrated in FIG. 2B.

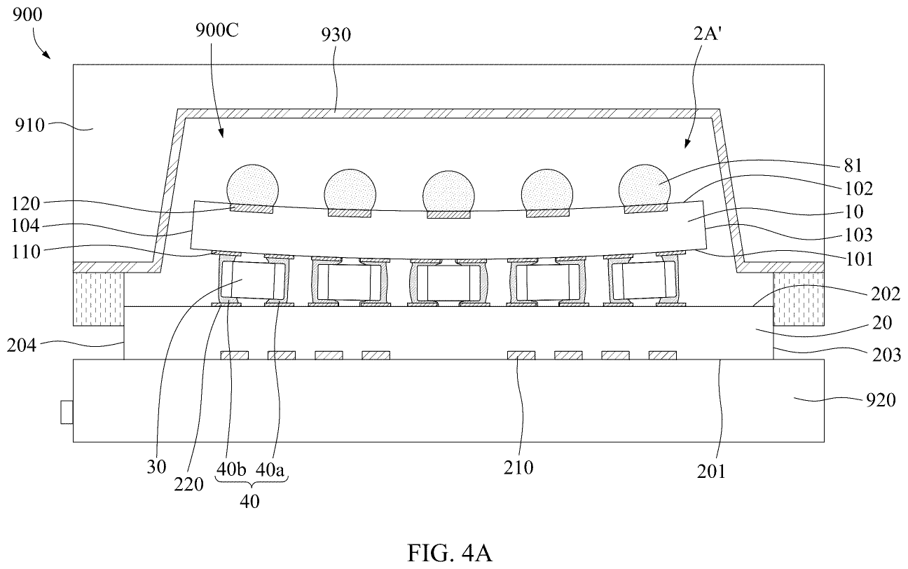

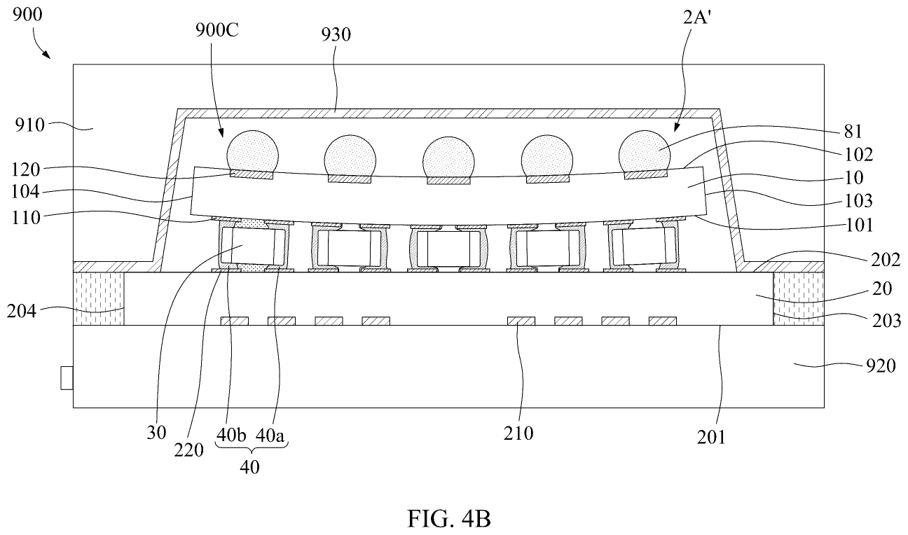

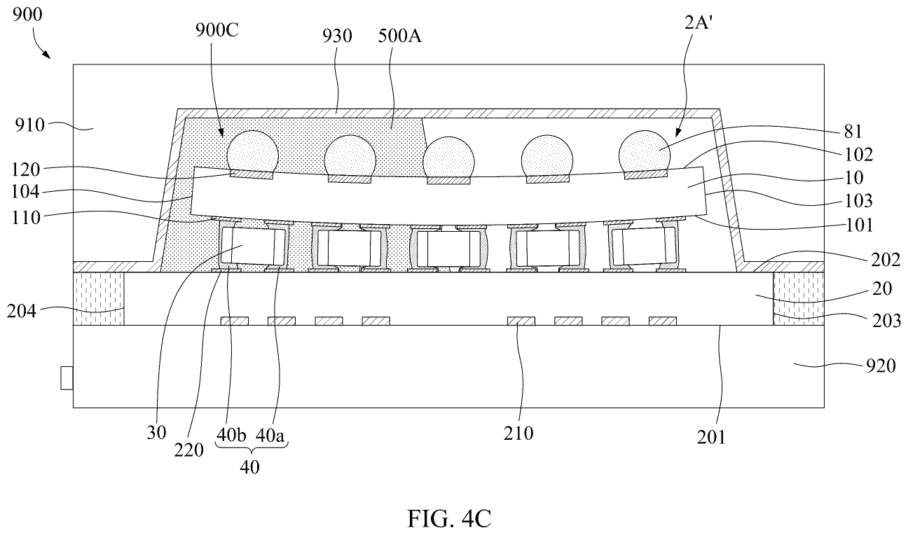

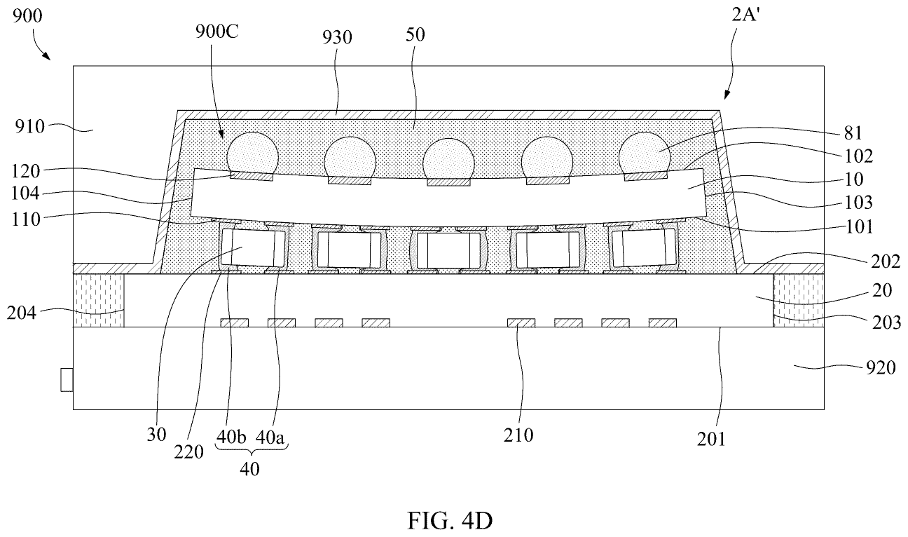

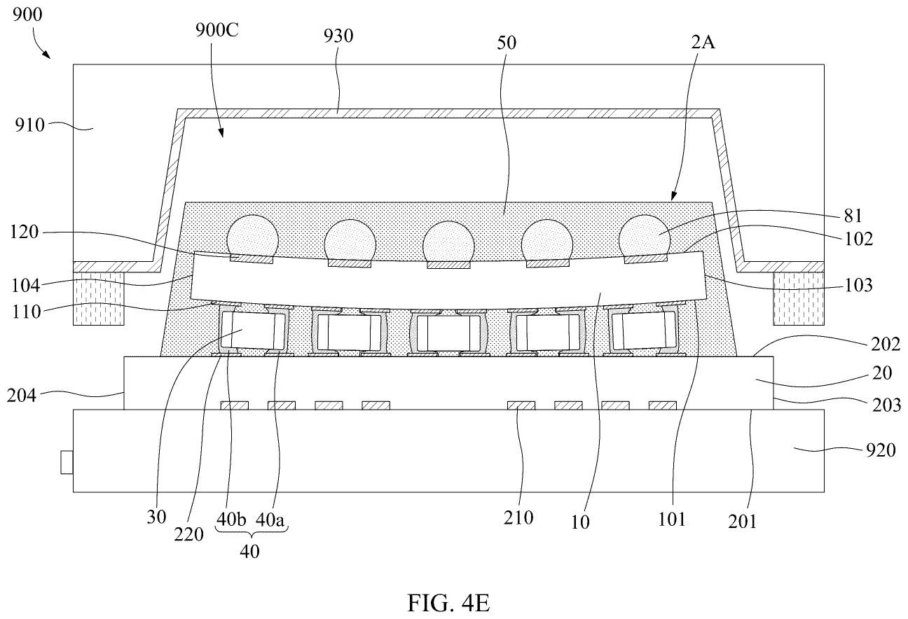

FIG. 4A to FIG. 4E illustrate various stages of an exemplary method of forming a package structure 2A in accordance with some arrangements of the present disclosure.

Referring to FIG. 4A, operations similar to those illustrated in FIG. 3A to FIG. 3C may be performed, except that a substrate 20 is used instead of a wafer-level substrate 20A, to form a structure 2A′ illustrated in FIG. 4A, and then the structure 2A′ is placed into a mold 900. The mold 900 may include an upper case 910 and a base 920 collectively define a space 900C for accommodating the structure 2A′. The mold 900 may further include a release film 930 on an inner surface of the upper case 910. In some arrangements, the structure 2A′ includes substrates 10 and 20 connected to each other through a single layer of passive components 30, reflowable elements 40 connecting the passive components 30 to the substrates 10 and 20, and electrical contacts 81 over the substrate 10. A warpage of the substrate 10 may be greater than a warpage of the substrate 20.

Referring to FIG. 4B, the upper case 910 may be pressed on edges of the substrate 20. In some arrangements, the electrical contacts 81 are spaced apart from the release film 930. The electrical contacts 81 and the surface 102 of the substrate 10 are free from being pressed by the upper case 910.

Referring to FIG. 4C, a protective material 500A may be disposed into the space 900C. The protective material 500A may be or include an encapsulant material. The encapsulant material may include an epoxy resin having fillers dispersed therein, a molding compound (e.g., an epoxy molding compound or other molding compound), polyimide (PI), a phenolic compound or material, a polymer material with silicone dispersed therein, or a combination thereof.

Referring to FIG. 4D, a pressure may be applied by the upper case 910 to the protective material 500A and the substrate 200 to resist or compensate the pressure from the flow of the protective material 500A. In some arrangements, the surface 102 of the substrate 10 is not pressed by the upper case 910. In some arrangements, the protective material 500A is cured to form a protective element 50. As such, the package structure 2A illustrated in FIG. 2A may be formed.

Referring to FIG. 4E, the package structure 2A may be removed from the mold 900.

In some cases wherein electrical contacts 81 are not formed on the surface 102 of the substrate 10, and the protective element 500 or the protective material 500A is disposed to expose the surface 102 during the stage illustrated in FIG. 3D or FIG. 4C, the upper case 910 may be pressed directly on the surface 102 of the substrate 10. With the pressure directly applied on the substrate 10, the reflowable element 40 may deform, delamination may occur between the reflowable element 40 and the substrates 10 and 20, and a serious warpage may occur to the substrate 10 in subsequent thermal operations. In addition, when the protective element 500 or the protective material 500A is disposed to expose the surfaces 102 of the substrates 10 and 10′ having different thicknesses during the stage illustrated in FIG. 3D or FIG. 4C, since the top surface of the protective element 500 or the protective material 500A may be formed uniform, the surface 102 of the thinner substrate 10′ may be covered by the protective element 500 or the protective material 500A when the top surface of the protective element 500 or the protective material 500A exposes the surface 102 of the thicker substrate 10. As a result, electrical contacts 81 cannot be connected to the surface 102.

In contrast, according to some arrangements of the present disclosure, the reflowable elements 40 are separated from the upper case 910 by a portion of the protective material 500A and thus are not subjected to relatively high pressure, and thus deformation of the reflowable elements 40 can be prevented effectively. In addition, the substrate 10 is pressed by the protective element 500 over the surface 102, and thus warpage of the substrate 10 is reduced. Therefore, delamination can be further prevented.

In addition, according to some arrangements of the present disclosure, the electrical contacts 81 are disposed on the surface 102 of the substrate 10 before the protective element 500 or the protective material 500A is formed on the surface 102. Therefore, the issue of the surface 102 of the substrate 10 being blocked by the protective element 500 or the protective material 500A can be solved.

Moreover, according to some arrangements of the present disclosure, the electrical contacts 81 are disposed on the surface 102 of the substrate 10 before the protective element 500 or the protective material 500A is formed on the surface 102. That is, the surface 102 is not exposed by the protective element 500 or the protective material 500A. Therefore, contamination (e.g., dusts or mold flash) on the surface 102 of the substrate 10 can be prevented, and thus additional operations for cleaning off the contamination can be omitted. Therefore, the yield can be increased.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first substrate;
a second substrate disposed over the first substrate;
a connection element comprising a first contact extending between the first substrate and the second substrate to connect the first substrate to the second substrate; and
a compression element disposed over the first substrate and comprising a portion extending from a top surface toward a bottom surface of the first substrate and configured to reduce warping of the first substrate in a first direction away from the second substrate.

2. The package structure as claimed in claim 1, wherein a distance between the first substrate and the second substrate is defined by a thickness of the connection element.

3. The package structure as claimed in claim 1, wherein the top surface of the first substrate faces the second substrate, the bottom surface of the first substrate is opposite to the top surface, and the compression element contacts the bottom surface.

4. The package structure as claimed in claim 1, further comprising a solder element engaged with a portion of the compression element and configured to provide a mold lock to increase a bonding strength between the compression element and the first substrate.

5. The package structure as claimed in claim 4, wherein the solder element has a width increasing along the first direction.

6. The package structure as claimed in claim 1, wherein the compression element is configured to press the first substrate by applying a force towards the second substrate.

7. The package structure as claimed in claim 6, wherein the top surface of the first substrate faces the second substrate, the bottom surface of the first substrate is opposite to the top surface, and the compression element extends from the bottom surface toward the top surface of the first substrate to connect to the second substrate.

8. The package structure as claimed in claim 1, further comprising a solder element extending between the first substrate and the second substrate and contacting the first contact of the connection element.

9. The package structure as claimed in claim 8, wherein the connection element further comprises a second contact opposite to the first contact and extending between the first substrate and the second substrate, the solder element comprises a first portion and a second portion contacting the first contact and the second contact of the connection element, and a height of the first portion is different from a height of the second portion.

10. The package structure as claimed in claim 8, wherein the solder element comprises a first portion contacting the first contact of the connection element and a pad of the second substrate, and a width of the first portion is greater than a thickness of the first portion.

11. The package structure as claimed in claim 10, wherein the solder element further comprises a second portion extending over the first contact, and a thickness of the second portion is less than the thickness of the first portion.

12. The package structure as claimed in claim 8, wherein a distance between the first substrate and the second substrate is defined by a height of the solder element.

13. A package structure, comprising:
a first substrate;
a second substrate disposed over the first substrate;
a first passive component and a second passive component connecting the first substrate to the second substrate, wherein the first passive component is closer to an edge of the first substrate than the second passive component is; and
a clamping mechanism encapsulating the first substrate, the first passive component and the second passive component and adhered to the second substrate, wherein the clamping mechanism comprises a first portion under the first passive component.

14. The package structure as claimed in claim 13, wherein the clamping mechanism comprises an encapsulant.

15. The package structure as claimed in claim 13, wherein the clamping mechanism contacts a top surface and a bottom surface of the first substrate, and a bottom surface of the clamping mechanism is spaced apart from the bottom surface of the first substrate by a non-uniform distance.

16. The package structure as claimed in claim 15, wherein the clamping mechanism further comprises a second portion adhered to the bottom surface of the second substrate and connected to the first portion.

17. The package structure as claimed in claim 13, wherein the clamping mechanism defines a plurality of cavities configured to accommodate a plurality of electrical contacts, and at least two of the cavities are recessed from a bottom surface of the clamping mechanism by different depths.

18. A package structure, comprising:
a first substrate having a first surface and a second surface opposite to the first surface;
a second substrate disposed over the first substrate;
a plurality of passive components arranged in a single layer and connecting the first substrate to the second substrate; and
a warpage control element between the first surface of the first substrate and the second substrate and extending over the second surface of the first substrate.

19. The package structure as claimed in claim 18, wherein at least two of the passive components are spaced apart from the first substrate by different distances.

20. The package structure as claimed in claim 18, further comprising a solder element contacting one of the passive components, a pad of the first substrate, and a pad of the second substrate.
